(19) United States
(12) Patent Application Publication
(10) Pub. No.: US 2016/0260855 A1
(43) Pub. Date: Sep. 8, 2016

(54) ASSEMBLIES OF SOLAR CELLS WITH CURVED EDGES

(71) Applicant: SolAero Technologies Corp., Albuquerque, NM (US)

(72) Inventors: Daniel Derkacs, Albuquerque, NM (US); Daniel Aiken, Cedar Crest, NM (US); Clay McPheeters, Albuquerque, NM (US); Lei Yang, Albuquerque, NM (US)

(21) Appl. No.: 15/058,805

(22) Filed: Mar. 2, 2016

Related U.S. Application Data
(60) Provisional application No. 62/128,132, filed on Mar. 4, 2015.

(51) Int. Cl. H01L 31/0352; H01L 31/047; H01L 31/0304

(52) U.S. Cl. CPC H01L 31/035281; H01L 31/0304; H01L 31/047

(57) ABSTRACT

Solar cells can be obtained by dividing a substantially circular solar cell wafer into portions featuring straight and arcuate edges, which are then combined to form solar cell arrays. The solar cells can be arranged in different ways, for example, with straight edges abutting against straight edges of adjacent solar cells, or with the solar cells in a row having at least one straight edge extending at an angle of between 50 and 70 degrees the direction of the row.

This application claims the benefit of U.S. Provisional Application No. 62/128,132, filed Mar. 4, 2015, which is incorporated herein by reference in its entirety

This application is related to U.S. patent application Ser. Nos. 14/498,071 filed Sep. 26, 2014, and 14/514,883 filed Oct. 15, 2014.

### BACKGROUND OF THE DISCLOSURE

1. Field of the Disclosure

The disclosure relates to the field of photovoltaic power devices, and more particularly arrays of discrete solar cells.

2. Description of the Related Art

Photovoltaic devices, such as photovoltaic modules or CIC (Solar Cell+Interconnects+Coverglass) devices, comprise one or more individual solar cells arranged to produce electric power in response to irradiation by solar light. Sometimes, the individual solar cells are rectangular, often square. Photovoltaic modules, arrays and devices including one or more solar cells may also be substantially rectangular, for example, based on an array of individual solar cells. Arrays of substantially circular solar cells are known to involve the drawback of inefficient use of the surface on which the solar cells are mounted, due to space that is not covered by the circular solar cells due to the space that is left between adjacent solar cells due to their circular configuration (cf. U.S. Pat. Nos. 4,235,643 and 4,321,417).

However, solar cells are often produced from circular or substantially circular wafers. For example, solar cells for space applications are typically multi junction solar cells grown on substantially circular wafers. These circular wafers are sometimes 100 mm or 150 mm diameter wafers. However, as explained above, for assembly into a solar array (henceforth, also referred to as a solar cell assembly), substantially circular solar cells, which can be produced from substantially circular wafers to minimize wasting wafer material and, therefore, minimize solar cell cost, are often not the best option, due to their low array packing factor, which increases the overall cost of the photovoltaic array or panel and implies an inefficient use of available space. Therefore the circular wafers are often divided into other form factors to make solar cells. The preferable form factor for a solar cell for space is a rectangle, such as a square, which allows for the area of a rectangular panel consisting of an array of solar cells to be filled 100% (henceforth, that situation is referred to as a “packing factor” of 100%), assuming that there is no space between the adjacent rectangular solar cells. However, when a single circular wafer is divided into a single rectangle, the wafer utilization is low. This results in waste. This is illustrated in FIG. 1, showing how conventionally, out of a circular solar cell wafer 100 a rectangular solar cell 1000 is obtained, leaving the rest of the wafer as waste 1001. This rectangular solar cell 1000 can then be placed side by side with other rectangular solar cells 1000 obtained from other wafers, thereby providing for efficient use of the surface on which the solar cells are placed (i.e., a high packing factor): a large W/m² ratio can be obtained, which depending on the substrate may also imply a high W/kg ratio, of great importance for space applications. That is, closely packed solar cells without any space between the adjacent solar cells is generally preferred, and especially for applications in which W/m² and/or W/kg are important aspects to consider. This includes space applications, such as solar power devices for satellites.

Space applications frequently use high efficiency solar cells, including multi junction solar cells and/or III/V compound semiconductor solar cells. High efficiency solar cell wafers are often costly to produce. Thus, the waste that has conventionally been accepted in the art as the price to pay for a high packing factor, that is, the waste that is the result of cutting the rectangular solar cell out of the substantially circular solar cell wafer, can imply a considerable cost.

Thus, the option of using substantially circular solar cells, corresponding to substantially circular solar cell wafers, to produce an array or assembly of solar cells, could in some cases become an interesting option. There is a trade-off between maximum use of the original wafer material and the packing factor. FIG. 2 shows how circular wafers can be packed according to a layout for maximum use of space, obtaining a packing factor in the order of 84%. This implies less wafer material is wasted than in the case of the option shown in FIG. 1, but also a less efficient use of the surface on which the solar cells are mounted, due to the lower packing factor. A further problem is that with this kind of layout, the pattern features a staggered distribution (schematically illustrated by the hexagon 2000 illustrated with broken lines in FIG. 2), which is non-optimal for producing a rectangular assembly of solar cells. The fact that the different rows of solar cells are staggered in relation to each other means that the assembly of solar cells will not fit neatly to the edges or boundaries of a rectangular panel. This implies an inefficient use of the space on the panel.

FIG. 3 schematically illustrates another prior art approach, where an octagonal solar cell 1002 (also known as a “square solar cell with cropped corners)” is produced from a circular wafer 100. FIG. 3 shows how the solar cell 1002 fits into a square D. Square units are useful for building assemblies because they can be rotated, simplifying assembly, without disrupting the array pattern. FIG. 3 illustrates how a square unit is derived from a square solar cell with truncated corners. This approach represents an improved wafer utilization compared to the approach of FIG. 1 as the waste 1001 of wafer material is less (frequently wafer utilization in the order of 70-80% is achieved), but it achieves only a moderate packing factor, for example, in the order of 85-95%.

### SUMMARY OF THE DISCLOSURE

A first aspect of the disclosure relates to a solar cell assembly comprising a plurality of solar cells, each solar cell of the plurality of solar cells being shaped as a portion of a circle, the portion having a surface area corresponding to not more than 50% of the surface area of the circle and not less than 25% of the surface area of the circle. That is, for example, each solar cell has a surface area that is not more than half of the surface area of the original circular solar cell wafer, but not less than a quarter thereof. The portion has at least two curved edges and at least two straight edges, each of the curved edges having a portion that has the shape of an arc of a circumference of the circle.

It has been found that this arrangement allows solar cells to be packed to form an array with a relatively high packing factor, while at the same time achieving a relatively low waste of wafer material, that is, a relatively high wafer utilization. For example, a substantially circular solar cell wafer can basically be divided into a few parts, such as into two parts or halves, by cutting in accordance with the diameter of the substantially circular wafer. Each of these two semicircles or similar can be provided with an additional straight portion by cropping it, before or after the division of the original wafer. For example, a circular solar cell wafer can be cropped at two diametrically opposite positions, in accordance with a chord at a radial distance of a few mm from the edge of the wafer, for example, at a radial distance of less than 10 mm in the case of a 100 mm wafer. If the initial solar cell wafer already features a straight portion in correspondence with its circumference, it can be sufficient to provide only one additional straight portion by cropping, in order to provide both solar cells, such as both semicircular solar cells, with two straight edges separating two arcuate edges.

By dividing the wafer into a relatively small number of discrete solar cells and without renouncing on the material adjacent to the circular or substantially circular edge of the solar cell wafer (except for the small segment of the circle that is cropped off), a high wafer utilization can be achieved. Solar cells obtained in this way can then be combined to provide an assembly with a relatively high packing factor, for example, with a packing factor in the order of, for example, 90%, while using more than for example 96% of the wafer material. Also, the fact that the solar cells are relatively large (for example, each solar cell can represent more than 30% or more than 40% or close to 50% of the wafer surface) is advantageous in that it may reduce the number of interconnections and the costs involved therewith, compared to for example a situation in which a wafer is divided into a large number of small solar cells. That is, the division of a solar cell wafer into a limited number of solar cells with arcuate edges and straight edges can help to strike an appropriate balance between high packing factor, limited waste of wafer material, and a relatively limited number of interconnections of solar cells.

In some embodiments of the disclosure, two of the straight edges are parallel. For example, a solar cell wafer can be cropped at two diametrically opposite ends and then divided along its diameter in parallel with the cropped edges, so that each of the resulting solar cells features two parallel straight edges.

In some embodiments of the disclosure, one of the straight edges is longer than another one of the straight edges. For example, the longer straight edge can correspond to the diameter of a substantially circular solar cell wafer, whereas the shorter straight edge can correspond to a chord of the circle represented by the solar cell wafer.

In some embodiments of the disclosure, the solar cells are arranged in rows and columns forming an array of solar cells, the columns extending in a first direction, the solar cells in a first column being arranged with the longer straight edge before the shorter straight edge in the first direction, the solar cells in a second column adjacent to the first column being arranged with the longer straight edge after the shorter straight edge in the first direction. That is, the solar cells in one column can for example be placed “upside down” compared to the solar cells in the adjacent column. This approach has been found to be appropriate for substantially semicircular cropped solar cells, which if arranged in this way allow the columns to partly overlap, thereby making efficient use of space.

In some embodiments of the disclosure, the curved edges are separated from each other by the straight edges. The straight edges can be arranged to abut against straight edges of adjacent solar cells in the array.

In some embodiments of the disclosure, a first one of the straight edges corresponds to a diameter of the circle. This is typically the case when a substantially circular solar cell wafer is divided into two halves.

In some embodiments of the disclosure, at least some of the solar cells are arranged with one of their straight edges abutting against a straight edge of a first adjacent solar cell, and with another one of their straight edges abutting against a straight edge of a second adjacent solar cell. In some embodiments, this helps to maximize the packing factor of the solar cell assembly.

In some embodiments of the disclosure, the solar cells are arranged in rows and columns forming an array of solar cells, wherein the rows extend in a first direction and the columns extend in a second direction, the second direction being perpendicular to the first direction. In some embodiments, at least one of the straight edges extends in a third direction, the third direction being at angle to the first direction, the angle being larger than 50 degrees and smaller than 70 degrees. It has been found that this can help to maximize the packing factor, especially in the case of large rectangular panels. For example, when substantially semicircular solar cells are used in a rectangular solar cell assembly, arranging them with their largest straight edge—such as the one corresponding to the diameter of the original substantially circular solar cell wafer—at an angle of between 50 and 70 degrees in relation to one of the sides of the rectangle, instead of parallel or perpendicular to that side, can help to increase the packing factor, especially for large rectangular panels. The local packing factor may be somewhat less in correspondence with the edges of the assembly, but this is made up for by a higher local packing factor within the panel. This solution can be especially attractive for large solar cell assemblies featuring a large number of solar cells.

In some embodiments of the disclosure, the solar cells are arranged forming an array with a plurality of columns and rows of solar cells, each column comprising a plurality of solar cells and each row comprising a plurality of solar cells, wherein the array of solar cells fits into a parallelogram shaped panel with a fill factor of not less than 89%, such as of more than 90%. As explained above, the invention makes it possible to combine a high packing factor with a relatively high wafer utilization, and without requiring the large number of interconnections that are needed when a solar cell wafer is divided into very many small solar cells, such as into solar cells each having a surface area of less than 10% of the wafer surface area.

In some embodiments of the disclosure, the solar cells are III-V compound semiconductor multijunction solar cells. The relatively high cost of this kind of solar cells means that a high wafer utilization can be especially important.

A further aspect of the disclosure relates to a solar cell assembly comprising a plurality of solar cells, each solar cell of the plurality of solar cells being shaped as a portion of a circle, the portion having at least one curved edge having a shape of an arc of a circumference of the circle, the portion further having at least one straight edge, the portion having a surface area corresponding to not more than 50% of a surface area of the circle and not less than 25% of the surface area of the circle, the solar cells being arranged in rows and columns forming an array of solar cells, wherein the rows extend in a first direction and the columns extend in a second direction, the second direction being at an angle to the first direction, the angle being less than 90 degrees.

Traditionally, solar cells have frequently been arranged in arrays in which columns and rows extend at 90 degrees to each other. However, it has been found that arranging rows and columns at an angle of less than 90 degrees can help to enhances packing factor when using solar cells with substantial circular arc shaped edges. Especially, it has been found that this can serve to enhance the packing factor in correspondence with the edges of the assembly. The array of solar cells can in some embodiments fit neatly into a parallelogram.

In some embodiments, each solar cell is shaped substantially as a semicircle.

In some embodiments, each solar cell has at least two straight edges. For example, each solar cell can feature one straight edge corresponding to the diameter of the original substantially circular solar cell wafer, and another straight edge corresponding to a chord of the circle. This kind of cropped semicircle has been found to allow for a good balance between packing factor and wafer utilization. In some embodiments, the two straight edges are parallel to each other. In some embodiments, two of the straight edges are parallel, one of the two parallel straight edges being longer than the other one of the two parallel straight edges. As explained, for example, the solar cells can be shaped as cropped semi-circles.

In some embodiments, each solar cell is shaped substantially as a sector of the circle corresponding to one third of the circle. It has been found that also this kind of solar cells makes it possible to achieve a high packing factor while minimizing waste of wafer material.

In some embodiments, the angle is between 45 degrees and 80 degrees, such as between 55 degrees and 70 degrees. It has been found that rows and columns extending at this angle in relation to each other can optimize the packing factor when the solar cells are shaped as substantial sectors of a circle, such as shaped as semicircles or cropped semicircles.

In some embodiments of the disclosure, the array of solar cells is shaped as a parallelogram that is adhered to a rectangular or parallelogram shaped panel.

A further aspect of the disclosure relates to a solar cell assembly comprising a plurality of solar cells, each solar cell of the plurality of solar cells being shaped as a portion of a circle, the portion having at least one curved edge and at least two straight edges, the portion having a surface area corresponding to not more than 50% of a surface area of the circle and not less than 25% of the surface area of the circle, the straight edges being at an angle of approximately 120 degrees to each other. In some embodiments, this can be achieved by dividing a substantially circular wafer into three substantially identical portions, each corresponding to a sector of the circle. In some embodiments, the circular arc edge can be additionally cropped to add further straight edges. It has been found that this kind of solar cells can be arranged to form a solar cell assembly with a relatively high packing factor. In some embodiments, each solar cell is shaped as the sector of a circle.

### BRIEF DESCRIPTION OF THE DRAWINGS

To complete the description and in order to provide for a better understanding of the disclosure, a set of drawings is provided. Said drawings form an integral part of the description and illustrate embodiments of the disclosure, which should not be interpreted as restricting the scope of the disclosure, but just as examples of how the disclosure can be carried out. The drawings comprise the following figures:

FIG. 1 schematically illustrates a prior art arrangement for producing a closely packed solar cell array out of square solar cells obtained from a circular solar cell wafer.

FIG. 2 schematically illustrates how circular solar cells packed to obtain a maximum packing factor imply a staggered arrangement of solar cells in an array of solar cells, or a solar cell assembly.

FIG. 3 schematically illustrates another prior art arrangement, based on the use of square solar cell with cropped corners obtained from a circular wafer.

FIG. 4 schematically illustrates how a substantially circular solar cell wafer can be divided into two substantially semicircular solar cells with cropped arcs, and how such solar cells can be combined to form solar cell arrays.

FIG. 5A schematically illustrates the effect of the angle θ in a solar cell assembly shaped as a parallelogram, on the cost per watt of panel and launch.

FIG. 5B schematically illustrates the effect of the angle θ in a solar cell assembly shaped as a parallelogram, on the packing factor.

FIGS. 6A-6C schematically illustrate an embodiment based on the use of solar cells shaped as circle sectors each corresponding to approximately one third of a solar cell wafer.

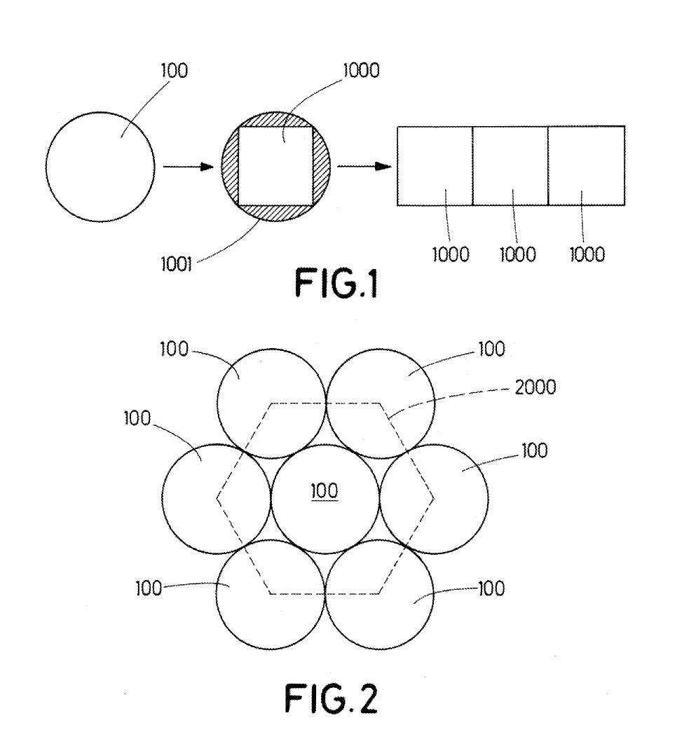

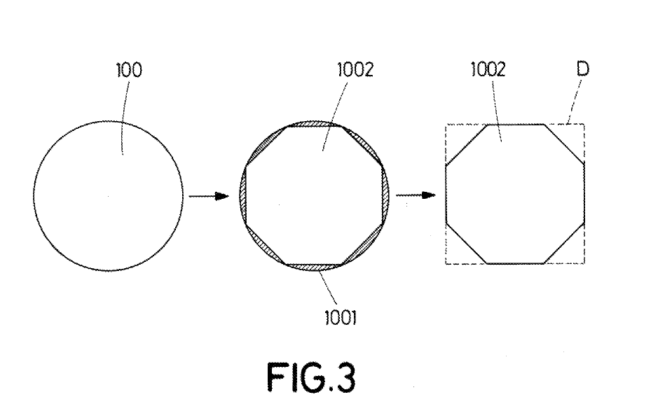

### DETAILED DESCRIPTION

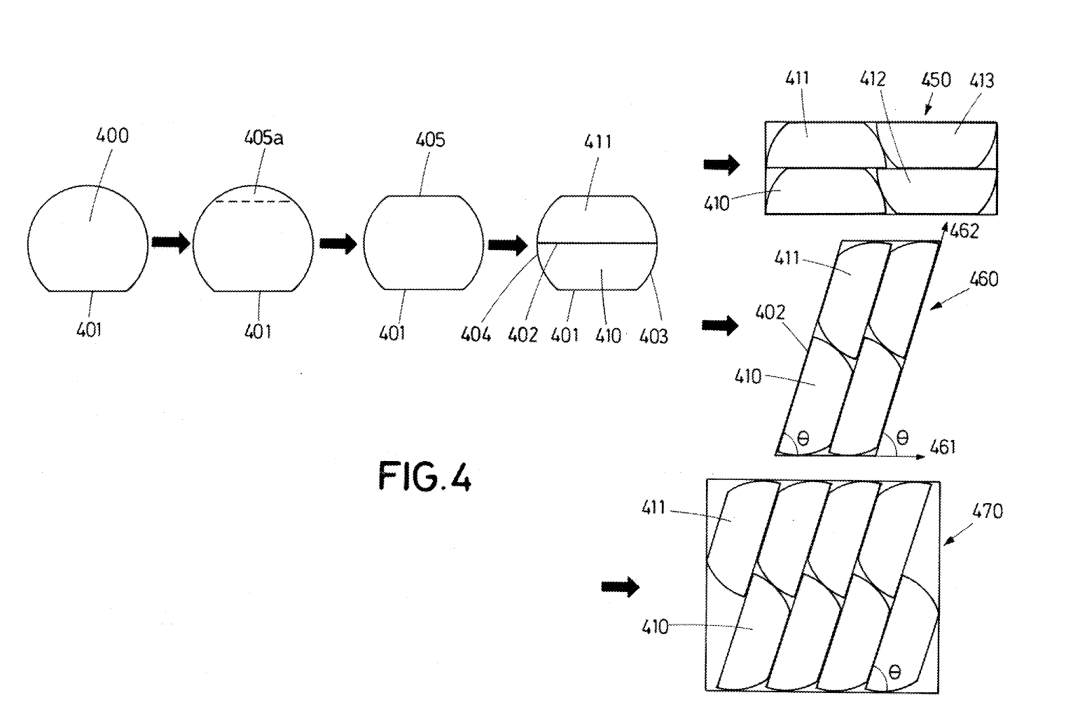

FIG. 4 shows how a substantially circular solar cell wafer 400 with a straight edge portion 401 can be provided with a further straight edge portion 405 by cropping it opposite to the first straight edge portion 401, removing a piece of wafer material 405a.

In the next step, the wafer is divided into two solar cells 410 and 411, by cutting the wafer in accordance with its diameter, in parallel with the straight edges 401 and 405. Thereby, two substantially identical solar cells 410 and 411 are obtained. Solar cell 410 comprises two parallel straight edges 401 and 402, one of which is longer than the other. The two straight edges 401 and 402 are separated from each other by two curved edges 403 and 404, each corresponding to an arc of the circular edge portion of the original wafer 400. In other embodiments, the wafer can be cut in other ways. It is clear that the surface area of each solar cell 410 and 411 is less than 50% of the surface area of the circle corresponding to the circular arc edge portion of the original wafer, but not less than 25% of the surface area of the circle. Dividing the wafer into a small number of relatively large solar cells can sometimes be preferred in order to minimize the number of interconnections needed for producing a solar cell assembly with a given area of solar cell material. That is, whereas the division of a solar cell wafer into a very large number of relatively small solar cells can allow for a high packing factor and high wafer utilization, the use of larger solar cells can be advantageous as fewer solar cells have to be interconnected, thereby reducing the cost of interconnection of the solar cells.

FIG. 4 schematically illustrates how solar cells obtained as described above can be combined into arrays to form solar cell assemblies with different layouts.

In one embodiment of the disclosure, a solar cell assembly 450 has a rectangular shape, in which the solar cells 410 and 411 are arranged so that in each column of the solar cell array, a shorter straight edge of one solar cell abuts against a longer straight edge of another solar cell. The solar cells in adjacent columns are arranged so that the solar cells 410 and 411 in one column are arranged with the shorter straight edge after the longer straight edge in a first direction, such as a direction extending vertically upwards from the bottom of the assembly, whereas the solar cells 412, 413 in the other column are arranged with their shorter straight edge before their longer straight edge, in the same direction. As illustrated in FIG. 4, this provides for a solar cell assembly 450 in which the columns are partially nested with each other, thereby providing for a fairly good packing factor. With semicircular solar cells a packing factor in the order of 84% is achieved, but it can be substantially enhanced by cropping the semicircles as described. For example, if a 100 mm wafer is cropped to 6 mm (in the radial direction), the resulting solar cells, shaped as cropped semicircles, allow for a packing factor of more than 89% when arranged as in the solar cell assembly 450, while wafer utilization is above 97%.

A second solar cell assembly 460 has the shape of a parallelogram. In the illustrated embodiment, the rows extend in a first direction 461 (here, the horizontal direction) and the columns extend in a second direction 462, at an angle θ to the first direction. This angle can preferably be between 45 and 80 degrees, more preferably between 55 and 70 degrees. It has been found that when the solar cells are shaped as perfect semicircles, an angle of about 60 degrees can be preferred (providing for a packing factor of more than 90%), whereas when solar cells shaped as semicircles but with a cropped edge parallel to the longest edge are used, the optimal angle may be in the order of 65 degrees. This arrangement provides for an even higher packing factor, and at the same time provides for a very low waste of wafer material. Basically, only the material 405a that is cropped off the wafer is wasted.

The arrangement of the solar cells with the longest straight edges at an angle θ of between 45 and 80 degrees to a side of the solar cell assembly, such as between 55 and 70 degrees, is also used in the solar cell assembly 470, but in this case the solar cell assembly has a rectangular shape. Here, the overall packing factor can be very good, especially in the case of a large solar cell assembly with a large number of solar cells in each column and row. The local packing factor is not very high in correspondence with the edges of the solar cell assembly, but higher away from the edges. Thus, this layout can be very attractive for large solar cell assemblies and provide for a good overall packing factor.

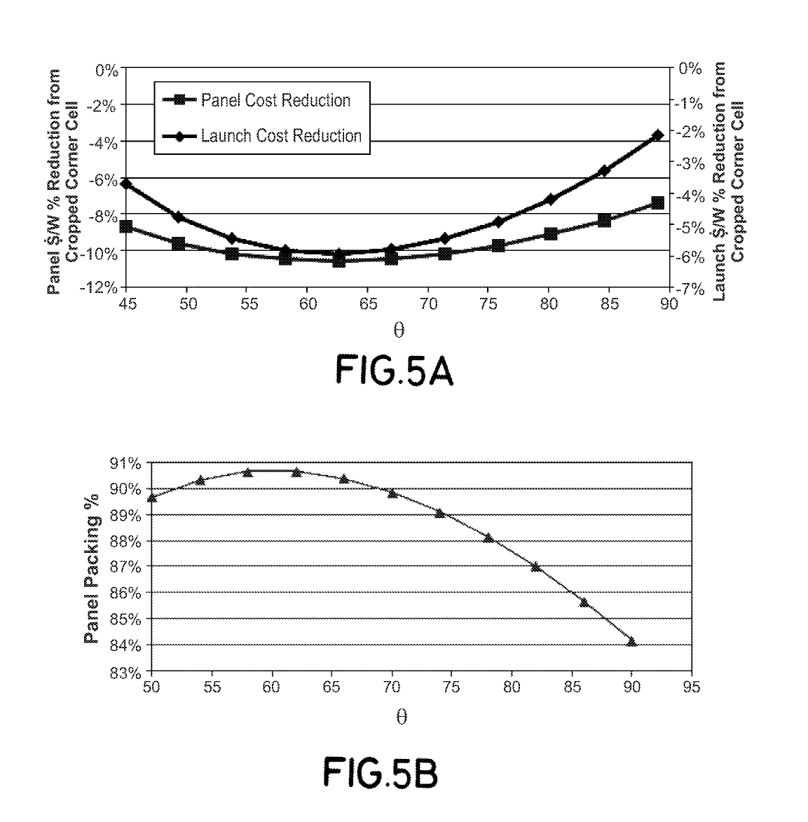

FIG. 5A schematically illustrates how the total panel cost per watt (left vertical axis) and the total launch cost (right vertical axis) can vary with the angle θ (the horizontal axis), in the case of the solar cell assembly 460, that is, the solar cell assembly shaped as a parallelogram and where the columns extend in a direction forming an angle θ with the rows, and where the longest straight edges of the substantially semicircular solar cells extend in parallel with the direction of the columns. This is expressed in terms of cost reduction in % compared to the traditional approach using one solar cell with cropped corners cut out of the wafer. FIG. 5B shows the impact of the angle θ on the panel packing factor. The panel packing factor has a substantial impact on the total launch cost per watt, as a high packing factor improves the watt/weight ratio. It is clear that the best results are obtained for an angle θ somewhere between 55 and 70 degrees.

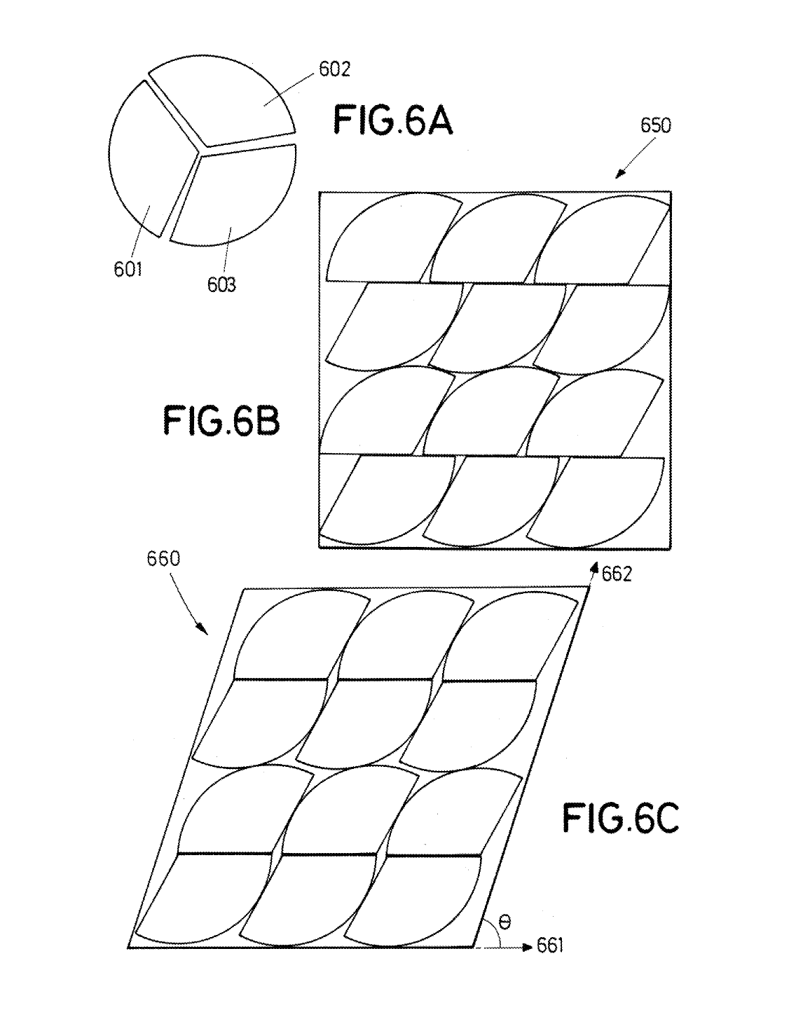

FIGS. 6A-6C schematically illustrate another embodiment. In this embodiment, a substantially circular solar cell wafer is divided into three substantially identical parts 601, 602, 603, each corresponding to a sector of the circle representing one third of the circle. That is, each solar cell comprises two straight edges extending at an angle of approximately 120 degrees to each other. This arrangement makes excellent use of the wafer material, and allows for a reasonable packing factor when the solar cells are arranged in a rectangular array 650 as shown in FIG. 6B. However, when arranged in an array adapted to fit into a parallelogram 660 with columns extending at an angle θ of less than 90 degrees in relation to the rows, an even better packing factor is obtained. This is shown in FIG. 6C, where the rows extend in a first direction 661 and the columns in a second direction 662 at an angle θ in relation to the first direction, so that the resulting array of solar cells has the shape of a parallellogram.

The packing factor referred to in this document is generally the local packing factor, which in many embodiments can differ from the overall packing factor of the solar cell assembly, for example due to a lower local packing factor in correspondence with the edges of the assembly (for example, due to the size and/or shape of the assembly), and/or due to the presence of other components on the solar cell assembly.

In this specification, the term “solar cell” refers to a solar cell that is an integral portion of a solar cell wafer, rather than a solar cell made up of a plurality of interconnected portions.

References to rows and columns of an array do not imply any specific orientation of the rows and columns, for example, rows are not necessarily oriented horizontally and columns are not necessarily oriented vertically. Rather, the references to rows and columns refer to solar cells arranged in a more or less regular pattern, wherein groups of solar cells can be identified in which the solar cells are arranged after each other. A group of solar cells in which the solar cells are arranged after each other in one direction can be considered a column, and a group of solar cells in which the solar cells are arranged after each other in a different direction can be regarded a column.

In this text, the term “comprises” and its derivations (such as “comprising”, etc.) should not be understood in an excluding sense, that is, these terms should not be interpreted as excluding the possibility that what is described and defined may include further elements, steps, etc.

The disclosure is obviously not limited to the specific embodiment(s) described herein, but also encompasses any variations that may be considered by any person skilled in the art (for example, as regards the choice of materials, dimensions, components, configuration, etc.), within the general scope of the disclosure as defined in the claims.

1. A solar cell assembly comprising a plurality of solar cells, each solar cell of the plurality of solar cells being shaped as a portion of a circle, the portion having a surface area corresponding to not more than 50% of a surface area of the circle and not less than 25% of the surface area of the circle, the portion having at least two straight edges, characterised in that the portion has at least two curved edges each having a shape of an arc of the circle.

2. The solar cell assembly according to claim 1, wherein two of the straight edges are parallel.

3. The solar cell assembly according to claim 1, wherein one of the straight edges is a longer straight edge and the other straight edge is a shorter straight edge.

4. The solar cell assembly according to claim 3, wherein the solar cells are arranged in rows and columns forming an array of solar cells, the columns extending in a first direction, the solar cells in a first column being arranged with the longer straight edge before the shorter straight edge in the first direction, the solar cells in a second column adjacent to the first column being arranged with the longer straight edge after the shorter straight edge in the first direction.

5. The solar cell assembly according to claim 1, wherein the curved edges are separated from each other by the straight edges.

6. The solar cell assembly according to claim 1, wherein a first one of the straight edges corresponds to a diameter of the circle.

7. The solar cell assembly according to claim 1, wherein at least some of the solar cells are arranged with one of their straight edges abutting against a straight edge of a first adjacent solar cell, and with another one of their straight edges abutting against a straight edge of a second adjacent solar cell.

8. The solar cell assembly according to claim 1, wherein the solar cells are arranged in rows and columns forming an array of solar cells, wherein the rows extend in a first direction and the columns extend in a second direction, the second direction being perpendicular to the first direction, wherein at least one of the straight edges extends in a third direction, the third direction being at angle to the first direction, the angle being larger than 50 degrees and smaller than 70 degrees.

9. The solar cell assembly according to claim 1, wherein the solar cells are arranged forming an array with a plurality of columns and rows of solar cells, each column comprising a plurality of solar cells and each row comprising a plurality of solar cells, wherein the array of solar cells fits into a parallelogram with a fill factor of not less than 84%.

10. The solar cell assembly according to claim 1, wherein the solar cells are III-V compound semiconductor multijunction solar cells.

11. A solar cell assembly comprising a plurality of solar cells, each solar cell of the plurality of solar cells being shaped as a portion of a circle, the portion having at least one curved edge having a shape of an arc of the circle, the portion further having at least one straight edge, the portion having a surface area corresponding to not more than 50% of a surface area of the circle and not less than 25% of the surface area of the circle, the solar cells being arranged in rows and columns forming an array of solar cells, wherein the rows extend in a first direction and the columns extend in a second direction, the second direction being at an angle to the first direction, the angle being less than 90 degrees.

12. The solar cell assembly according to claim 11, wherein each solar cell is shaped substantially as a semicircle.

13. The solar cell assembly according to claim 11, wherein each solar cell has at least two straight edges.

14. The solar cell assembly according to claim 13, wherein the two straight edges are parallel, one of the two parallel straight edges being longer than the other one of the two parallel straight edges.

15. The solar cell assembly according to claim 11, wherein each solar cell is shaped substantially as a sector of the circle corresponding to one third of the circle.

16. The solar cell assembly according to claim 11, wherein the angle is between 45 degrees and 80 degrees.

17. The solar cell assembly according to claim 16, wherein the angle is between 55 degrees and 70 degrees.

18. The solar cell assembly of claim 11, wherein the array is shaped as a parallellogram

19. A solar cell assembly comprising a plurality of solar cells, each solar cell of the plurality of solar cells being shaped as a portion of a circle, the portion having at least one curved edge and at least two straight edges, the curved edge each having a shape of an arc of a circumference of the circle, the portion having a surface area corresponding to not more than 50% of a surface area of the circle and not less than 25% of the surface area of the circle, the straight edges being at an angle of approximately 120 degrees to each other.

20. The solar cell assembly according to claim 19, wherein each solar cell is shaped as the sector of a circle.
